(19) United States
(12) Patent Application Publication
(10) Pub. No.: US 2024/0165675 A1
(43) Pub. Date: May 23, 2024

(54) SUBSTRATE CLEANING APPARATUS, SUBSTRATE PROCESSING APPARATUS, APPARATUS FOR CLEANING CLEANING MEMBER, AND METHOD FOR CLEANING CLEANING MEMBER

(71) Applicant: EBARA CORPORATION, Tokyo (JP)

(72) Inventors: Yosuke HIMORI, Tokyo (JP); Koichi FUKAYA, Tokyo (JP)

(21) Appl. No.: 18/514,511

(22) Filed: Nov. 20, 2023

(30) Foreign Application Priority Data
Nov. 22, 2022 (JP) 2022-186506

(51) Int. Cl. B08B 1/40; B08B 1/36

(52) U.S. Cl. CPC B08B 1/40; B08B 1/36

(57) ABSTRACT

According to one embodiment, provided is a substrate cleaning apparatus including: a cleaning member configured to clean a substrate; a plate having a horizontal plane provided with a hole; and a pressing mechanism configured to press the cleaning member vertically downward against the plate, wherein the hole penetrates the plate, and a liquid discharged from the cleaning member is discharged below via the hole, whereby absorption of the liquid discharged from the cleaning member into the cleaning member is suppressed.

### CROSS-REFERENCE TO RELATED APPLICATIONS

This application claims the benefit of Japanese Priority Patent Application JP 2022-186506 filed on Dec. 22, 2022, the entire contents of which are incorporated herein by reference.

### FIELD

The present disclosure relates to a substrate cleaning apparatus, a substrate processing apparatus, an apparatus for cleaning a cleaning member, and a method for cleaning a cleaning member.

### BACKGROUND

A substrate processing apparatus having a substrate polishing apparatus for polishing a substrate and a substrate cleaning apparatus for cleaning a polished substrate is known. In the substrate cleaning apparatus, the substrate is cleaned by using a cleaning member, but the cleaning member itself is contaminated by cleaning. Therefore, it is necessary to clean the cleaning member.

### CITATION LIST

### Patent Literature

Patent Literature 1: JP 6054805 B2
Patent Literature 2: JP 2020-123647 A
Patent Literature 3: JP H10-223583 A

### SUMMARY

[1] According to one embodiment, provided is a substrate cleaning apparatus comprising: a cleaning member configured to clean a substrate; a plate having a horizontal plane provided with a hole; and a pressing mechanism configured to press the cleaning member vertically downward against the plate, wherein the hole penetrates the plate, and a liquid discharged from the cleaning member is discharged below via the hole, whereby absorption of the liquid discharged from the cleaning member into the cleaning member is suppressed.

[2] The substrate cleaning apparatus according to [1], may further comprises: a casing provided in a lower portion of the plate; and a depressurizing mechanism configured to depressurize an inside of the casing.

[3] The substrate cleaning apparatus according to [1] or [2], may further comprises a nozzle configured to supply a cleaning liquid to the plate.

[4] The substrate cleaning apparatus according to one of [1] to [4], wherein the pressing mechanism may rotate the cleaning member while pressing the cleaning member against the plate.

[5] The substrate cleaning apparatus according to [4], wherein the hole may not be provided at a position where the cleaning member comes into contact in the plate.

[6] The substrate cleaning apparatus according to one of [1] to [5], may further comprises a heating member configured to heat the plate.

[7] The substrate cleaning apparatus according to one of [1] to [6], may further comprises a sensor provided at a position in contact with the cleaning member and capable of detecting a contamination state of the cleaning member.

[8] The substrate cleaning apparatus according to [7], wherein the plate may be provided with a second hole for sensor arrangement, and the sensor may be provided in the second hole.

[9] The substrate cleaning apparatus according to [8], wherein an upper surface of the sensor and an upper surface of the plate may be substantially flush with each other.

[10] The substrate cleaning apparatus according to one of [7] to [9], wherein the sensor may be a pH measuring instrument or a conductivity meter.

[11] The substrate cleaning apparatus according to one of [1] to [10], may further comprises a substrate holding and rotating mechanism configured to hold and rotate a substrate in a horizontal direction, wherein a lower surface of the cleaning member cleans an upper surface of the substrate, and the pressing mechanism presses the lower surface of the cleaning member against the plate.

[12] The substrate cleaning apparatus according to [11], wherein the pressing mechanism may be a swing arm, when cleaning the substrate, the swing arm swings the cleaning member on the substrate while the swing arm presses the cleaning member vertically downward against the upper surface of the substrate, and when cleaning the cleaning member, the swing arm presses the cleaning member vertically downward against the plate.

[13] According to one embodiment, provided is a substrate processing apparatus comprising: a substrate polishing apparatus configured to polish a substrate using a slurry; the substrate cleaning apparatus according to one of [1] to [12] that cleans the polished substrate; and a substrate drying apparatus configured to dry the cleaned substrate.

[14] According to one embodiment, provided is an apparatus for cleaning a cleaning member, the apparatus comprising: a plate having a horizontal plane provided with a hole; and a pressing mechanism configured to press a cleaning member for cleaning a substrate vertically downward against the plate, wherein the hole penetrates the plate, and a liquid discharged from the cleaning member is discharged below via the hole, whereby absorption of the liquid discharged from the cleaning member into the cleaning member is suppressed.

[15] According to one embodiment, provided is a method for cleaning a cleaning member, the method comprising a process of pressing a cleaning member for cleaning a substrate vertically downward against a plate having a horizontal plane provided with a hole, wherein the hole penetrates the plate, and a liquid discharged from the cleaning member is discharged below via the hole, whereby absorption of the liquid discharged from the cleaning member into the cleaning member is suppressed.

### BRIEF DESCRIPTION OF DRAWINGS

FIG. 1 is a schematic configuration view of a substrate processing apparatus;

FIG. 2A is a schematic top view of a substrate cleaning apparatus according to an embodiment;

FIG. 2B is a schematic side view of the substrate cleaning apparatus according to the embodiment;

FIG. 3 is a schematic view of a self-cleaning apparatus;

FIG. 4A is a view schematically illustrating a state in which the self-cleaning apparatus according to the present embodiment cleans a cleaning member;

FIG. 4B is a view schematically illustrating a state in which a self-cleaning apparatus according to a comparative example cleans the cleaning member;

FIG. 5 is a view schematically illustrating a self-cleaning apparatus according to another comparative example;

FIG. 6 is a schematic view of a first modification of the self-cleaning apparatus;

FIG. 7 is a schematic view of a second modification of the self-cleaning apparatus;

FIG. 8 is a schematic view of a third modification of the self-cleaning apparatus; and

FIG. 9 is a schematic view of a fourth modification of the self-cleaning apparatus.

### DETAILED DESCRIPTION

Hereinafter, an embodiment according to the present invention will be specifically described with reference to the drawings.

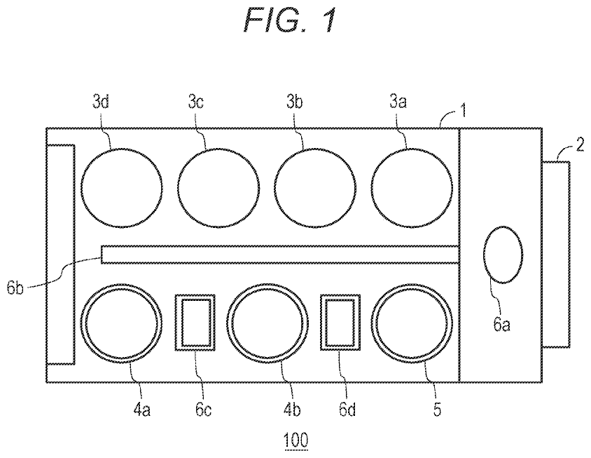

FIG. 1 is a schematic configuration view of a substrate processing apparatus 100. The substrate processing apparatus 100 is, for example, a CMP apparatus, and includes a substantially rectangular housing 1 and a load port 2 disposed adjacent to the housing 1.

A substrate cassette (not illustrated) for stocking a plurality of substrates W is placed on the load port 2. Examples of the substrate W include a semiconductor wafer. However, the substrate W to be processed is not limited to the semiconductor wafer, and may be another type of substrate used for manufacturing a semiconductor apparatus such as a glass substrate or a ceramic substrate. In addition, a semiconductor film, a metal film, or the like is formed on at least one surface of the substrate W.

The substrate processing apparatus 100 includes one or more (four in FIG. 1) substrate polishing apparatuses 3a to 3d (when they are not particularly distinguished, they may be collectively referred to as a “substrate polishing apparatus 3”), one or more (two in FIG. 1) substrate cleaning apparatuses 4a and 4b (when they are not particularly distinguished, they may be collectively referred to as a “substrate cleaning apparatus 4”), and one or more (one in FIG. 1) substrate drying apparatuses 5, which are disposed inside the housing 1.

As an example, the substrate polishing apparatuses 3a to 3d are disposed along one side of the housing 1 in a longitudinal direction. The substrate cleaning apparatuses 4a and 4b and the substrate drying apparatus 5 are disposed along the other side of the housing 1 in the longitudinal direction.

The substrate polishing apparatus 3 polishes a surface of the substrate W. More specifically, the substrate polishing apparatus 3 supplies a slurry onto the substrate W while rotating the substrate W, and polishes the surface of the substrate W by pressing a polishing member (not illustrated) against the surface of the substrate W. A polishing waste or a slurry may remain on the polished substrate W.

The substrate cleaning apparatus 4 cleans the surface of polished the substrate W. More specifically, the substrate cleaning apparatus 4 cleans the surface of the substrate W by pressing a cleaning member (not illustrated in FIG. 1) against the surface of the substrate W while rotating the substrate W. The cleaning member may be contaminated by the polishing waste or the slurry remaining on the polished substrate W. In addition, when a chemical liquid is supplied onto the substrate W during cleaning, the cleaning member may be contaminated by the chemical liquid.

Therefore, in the present embodiment, an apparatus for cleaning a cleaning member (hereinafter, referred to as “self-cleaning apparatus”, and cleaning the cleaning member may be referred to as “self-cleaning”) is provided in the substrate cleaning apparatus 4. A configuration example of such a substrate cleaning apparatus 4 will be described later.

The substrate drying apparatus 5 dries the surface of the cleaned substrate W.

In addition, the substrate processing apparatus 100 includes substrate transport apparatuses 6a to 6d (when they are not particularly distinguished, they may be collectively referred to as a “substrate transport apparatus 6”), which are disposed inside the housing 1.

The substrate transport apparatus 6a is disposed adjacent to the load port 2. The substrate transport apparatus 6a receives an unprocessed substrate W from the load port 2 and transfers the substrate W to the substrate transport apparatus 6b, or receives a processed substrate W from the substrate transport apparatus 6b.

The substrate transport apparatus 6b extends in the longitudinal direction at a central portion of the housing 1. The substrate transport apparatus 6b receives an unprocessed substrate W from the substrate transport apparatus 6a and transports the substrate W to any one of the substrate polishing apparatuses 3a to 3d, receives the substrate W after polishing from the substrate polishing apparatuses 3a to 3d and transfers the substrate W to the substrate transport apparatus 6c, or receives a dried substrate W from the substrate transport apparatus 6d and transfers the substrate W to the substrate transport apparatus 6a.

The substrate transport apparatus 6c is disposed between the substrate cleaning apparatuses 4a and 4b. The substrate transport apparatus 6c receives the polished substrate W from the substrate transport apparatus 6b and transports the substrate W to either the substrate cleaning apparatus 4a or 4b, or receives the substrate W after cleaning from the substrate cleaning apparatus 4a and transports the substrate W to the substrate cleaning apparatus 4b.

The substrate transport apparatus 6d is disposed between the substrate cleaning apparatus 4b and the substrate drying apparatus 5. The substrate transport apparatus 6d receives the substrate W after cleaning from the substrate cleaning apparatus 4b and transports the substrate W to the substrate drying apparatus 5, or receives the substrate W after drying from the substrate drying apparatus 5 and transfers the substrate W to the substrate transport apparatus 6b.

Note that arrangement of the substrate polishing apparatus 3, the substrate cleaning apparatus 4, the substrate drying apparatus 5, and the substrate transport apparatus 6 is merely an example. One or more substrate transport apparatuses 6 may be provided such that a substrate W can be transported in the order of the substrate polishing apparatus 3, the substrate cleaning apparatus 4, and the substrate drying apparatus 5.

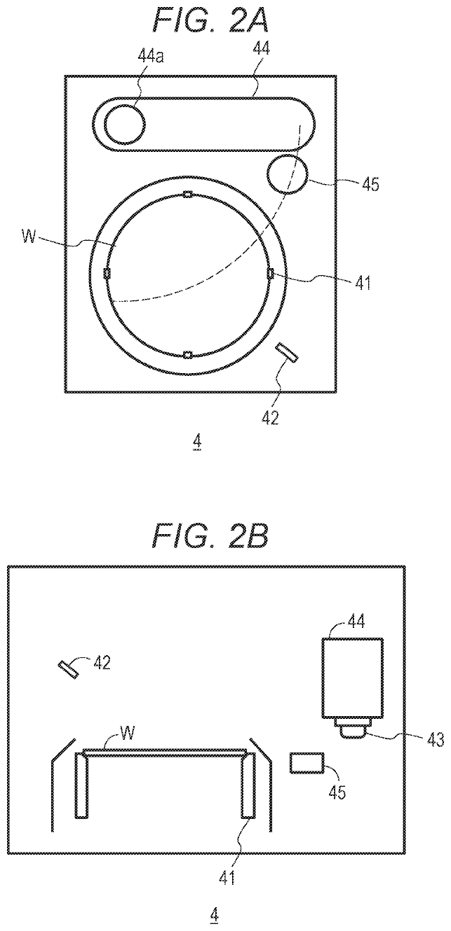

FIGS. 2A and 2B are a schematic top view and a schematic side view, respectively, of the substrate cleaning apparatus 4 according to the embodiment. The substrate cleaning apparatus 4 has a substrate holding and rotating mechanism 41, a cleaning liquid supply nozzle 42, a cleaning member 43, a swing arm 44, and a self-cleaning apparatus 45.

The substrate holding and rotating mechanism 41 holds and rotates a substrate W. In the present embodiment, the substrate holding and rotating mechanism 41 holds a substrate W in a horizontal direction, and rotates the substrate W in a horizontal plane with a vertical axis passing through a center of the substrate W as a rotation axis.

The cleaning liquid supply nozzle 42 supplies a cleaning liquid onto an upper surface of the substrate W. The cleaning liquid supply nozzle 42 may include at least one of a pure water nozzle for supplying pure water and a chemical liquid nozzle for supplying a chemical liquid.

The cleaning member 43 comes into contact with the upper surface of the substrate W to clean the substrate W. In the present embodiment, the cleaning member 43 is a pencil type. The cleaning member 43 is, for example, a PVA sponge, and has water absorbency. Therefore, by cleaning the polished substrate W, a cleaning liquid (including a chemical liquid) including a polishing waste and a slurry is absorbed into the cleaning member 43.

The swing arm 44 is provided with a swing shaft 44a on one end side, and holds the cleaning member 43 downward on the other end side. When cleaning the substrate W, the swing arm 44 swings the cleaning member 43 on the substrate W while pressing the cleaning member 43 vertically downward against the upper surface of the substrate W. As a result, a lower surface of the cleaning member 43 cleans the upper surface of the substrate W. When the substrate W is not cleaned, the swing arm 44 moves the cleaning member 43 to a standby position outside a position where the substrate W is held.

The self-cleaning apparatus 45 is disposed at a position away from the position where the substrate W is held and in the vicinity of a retracted position. Then, the self-cleaning apparatus 45 self-cleans the cleaning member 43.

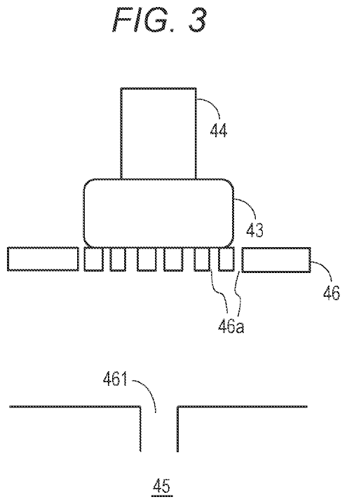

FIG. 3 is a schematic view of the self-cleaning apparatus 45. The self-cleaning apparatus 45 may include a plate 46 and the swing arm 44. The plate 46 is disposed so as to expand in the horizontal direction, and one or more holes 46a penetrating the plate 46 in a vertical direction are provided. It can also be said that the plate 46 has a horizontal plane provided with the holes 46a. The swing arm 44 holds the cleaning member 43 downward and presses the cleaning member 43 vertically downward against the plate 46.

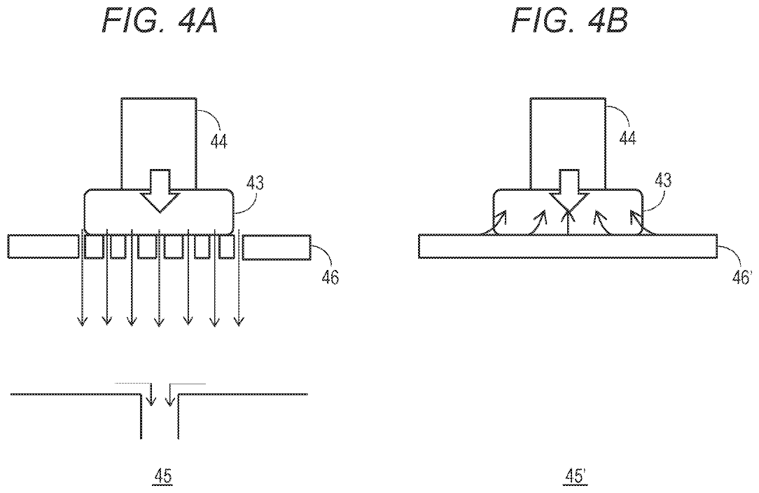

FIG. 4A is a view schematically illustrating a state in which the self-cleaning apparatus 45 according to the present embodiment cleans the cleaning member 43. The swing arm 44 presses the lower surface of the cleaning member 43 vertically downward against the plate 46. As a result, the liquid contaminated with a polishing waste and a slurry that has been absorbed into the cleaning member 43 is discharged. The liquid discharged from the cleaning member 43 falls below by gravity via the holes 46a of the plate 46, and is discharged from a discharger 461. Therefore, the contaminated liquid is suppressed from being reabsorbed into the cleaning member 43. Accordingly, the cleaning member 43 can be efficiently self-cleaned. It is desirable to repeat pressing and releasing the pressure with respect to the cleaning member 43 a plurality of times.

In view of such an operation of the self-cleaning apparatus 45, the swing arm 44 can be referred to as a pressing mechanism, and the plate 46 can be referred to as a pressed member. In addition, the number, arrangement position, size, shape, and the like of the holes 46a provided in the plate 46 are not particularly limited as long as the liquid from the cleaning member 43 can be discharged below the plate 46. As an example, the holes 46a may be circular with a diameter of less than 1 mm. Further, instead of the plate 46, a pressed member having a horizontal plane provided with a hole but not having a plate shape may be applied.

FIG. 4B is a view schematically illustrating a state in which a self-cleaning apparatus 45′ according to a comparative example cleans the cleaning member 43. In the present comparative example, the plate 46 of the present embodiment is replaced with a plate 46′ having no hole. The swing arm 44 presses the lower surface of the cleaning member 43 vertically downward against the plate 46′. As a result, the liquid contaminated with a polishing waste and a slurry that has been absorbed into the cleaning member 43 is discharged. The liquid discharged from the cleaning member 43 remains on the plate 46′. Therefore, when the pressing against the cleaning member 43 is stopped, the contaminated liquid remaining on the plate 46′ is reabsorbed into the cleaning member 43. As a result, it is difficult to efficiently self-clean the cleaning member 43.

As is apparent from comparison between FIGS. 4A and 4B, in the present embodiment, since the cleaning member 43 is pressed against the plate 46 provided with the holes 46a to clean the cleaning member 43, the liquid from the cleaning member 43 is discharged from the holes 46a and this liquid can be prevented from being reabsorbed into the cleaning member 43. Therefore, in the present embodiment, the cleaning member 43 can be efficiently self-cleaned.

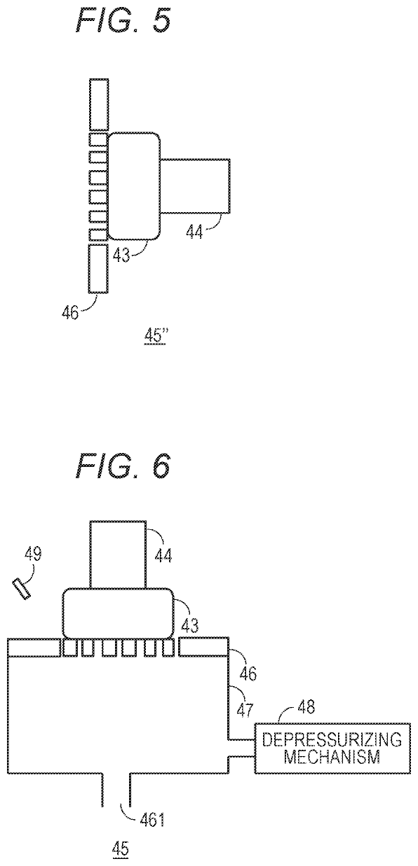

FIG. 5 is a view schematically illustrating a self-cleaning apparatus 45″ according to another comparative example. In the present comparative example, the plate 46 of the present embodiment is disposed in the vertical direction. According to such a comparative example, the cleaning member 43 is held downward when cleaning the substrate W, and the cleaning member 43 is held sideways when self-cleaning the cleaning member 43, such that a mechanically complicated structure is required.

On the other hand, in the present embodiment, since both the substrate W to be cleaned and the plate 46 are disposed in the horizontal direction, it is sufficient that the cleaning member 43 is directed downward when cleaning the substrate W and when self-cleaning the cleaning member 43, and the structure of the swing arm 44 can be simplified.

Some modifications will be described below.

FIG. 6 is a schematic view of a first modification of the self-cleaning apparatus 45.

The self-cleaning apparatus 45 may have a casing 47 provided below the plate 46 and a depressurizing mechanism 48 that depressurizes the inside of the casing 47. By depressurizing the inside of the casing 47, it is possible to more efficiently discharge the liquid from the cleaning member 43 below the plate 46 as compared with the discharge of the liquid only by gravity.

The self-cleaning apparatus 45 may have a pressure gauge (not illustrated) that measures a pressure in the casing 47. By monitoring the pressure (in particular, a behavior of depressurization) in the casing 47, it is possible to detect that the holes 46a are clogged by a slurry or the like.

Further, the self-cleaning apparatus 45 may have one or more nozzles 49 for supplying a cleaning liquid to the plate 46. The cleaning liquid may be one or more of a chemical liquid and functional water (for example, electrolytic water and fine bubble water) suitable for removing a contamination source such as pure water and a slurry. In addition, the cleaning liquid may be adjusted to a temperature suitable for removing the contamination source such as a slurry.

By supplying the cleaning liquid from the nozzle 49, the cleaning liquid not contaminated from the nozzle 49 is absorbed into the cleaning member 43 when the pressing against the cleaning member 43 is stopped. As a result, the contaminated liquid included in the cleaning member 43 can be efficiently replaced. In addition, by supplying the cleaning liquid, it is also possible to maintain an environment in which precipitates do not grow.

In the present modification, the casing 47 also has a function of a gas-liquid separation tank, and the liquid discharged to the casing 47 is discharged through the discharger 461. However, the gas-liquid separation tank may be separately provided between the casing 47 and the depressurizing mechanism 48.

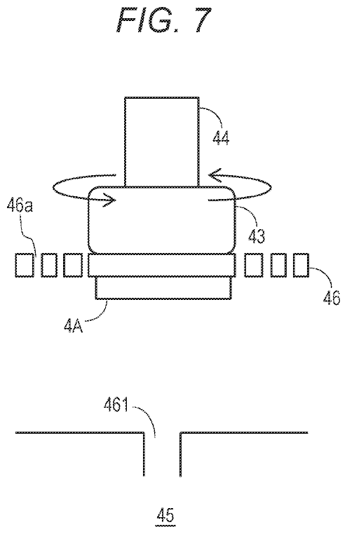

FIG. 7 is a schematic view of a second modification of the self-cleaning apparatus 45.

The swing arm 44 may not only press the cleaning member 43 vertically downward, but also rotate the cleaning member 43 about a vertical axis passing through a center of a horizontal cross section of the cleaning member 43. As a result, the cleaning member 43 rotates in the horizontal plane in a state where the lower surface of the cleaning member 43 is pressed against the plate 46. Therefore, the contaminated liquid included in the cleaning member 43 can be quickly discharged.

Here, it is desirable that the holes 46a are not provided at a position of the plate 46 with which the cleaning member 43 comes into contact and the plate is flat. In other words, it is desirable that the holes 46a are provided only at a position of the plate 46 with which the cleaning member 43 does not come into contact. This is because, when the holes 46a are provided at a position of the plate 46 with which the cleaning member 43 comes into contact, the cleaning member 43 may be worn when the rotating cleaning member 43 comes into contact with an edge of the hole 46a.

Further, the self-cleaning apparatus 45 may have a heating member 4A that heats the plate 46 to a temperature suitable for removing a contamination source such as a slurry. The heating member 4A is desirably provided, for example, on the lower surface of the plate 46 at a position facing a position of the plate 46 with which the cleaning member 43 is in contact.

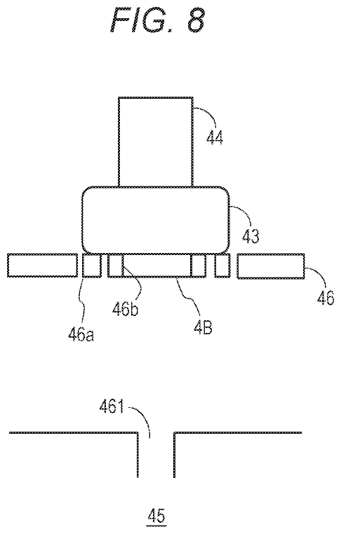

FIG. 8 is a schematic view of a third modification of the self-cleaning apparatus 45.

The self-cleaning apparatus 45 may have a sensor 4B capable of detecting a contamination state of the cleaning member 43. The sensor 4B is desirably provided at a position in contact with the cleaning member 43 so that the inside of the cleaning member 43 can be measured. As a specific example, a hole 46b for sensor arrangement is provided in the plate 46, and the sensor 4B is disposed in the hole 46b such that an upper surface of the sensor 4B and an upper surface of the plate 46 are substantially flush with each other. The term “substantially flush” means that the upper surface of the sensor 4B may be slightly lower than the upper surface of the plate 46 as long as the liquid inside the cleaning member 43 can be measured, and the upper surface of the sensor 4B may be slightly higher than the upper surface of the plate 46 as long as the cleaning member 43 is not damaged during self-cleaning of the cleaning member 43.

However, the sensor 4B only needs to be able to measure a contamination degree of the liquid seeping from the cleaning member 43, and it is not essential that the sensor 4B be in contact with the cleaning member 43.

As an example, the sensor 4B is a pH measuring instrument. When the contamination source is an acidic or alkaline chemical liquid, the contamination state of the cleaning member 43 can be detected by measuring the pH. As another example, the sensor 4B may be a conductivity meter. When the contamination source contains metal ions, the contamination state of the cleaning member 43 can be detected by measuring the conductivity.

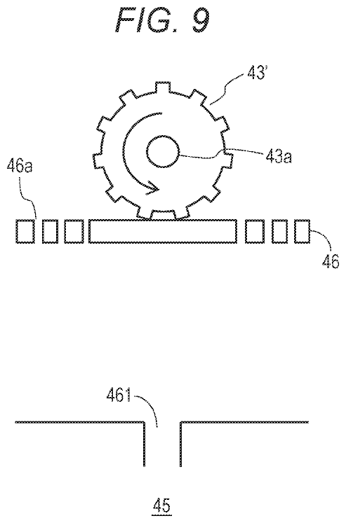

FIG. 9 is a schematic view of a fourth modification of the self-cleaning apparatus 45. In the present modification, a roll-type cleaning member 43′ is self-cleaned. The cleaning member 43′ has a shape in which a large number of nodules protrude in a radial direction from a surface of a columnar cleaning member main body extending to a back side of the drawing. A rotation mechanism 43a that rotates the cleaning member 43′ about the longitudinal axis is provided. The rotation mechanism 43a also functions as a pressing member that presses the cleaning member 43′ vertically downward against the plate 46.

For the same reason as described in FIG. 7, it is desirable that the holes 46a are not provided at the position of the plate 46 with which the cleaning member 43′ comes into contact, and the plate is flat.

Some of the embodiments and modifications described above may be arbitrarily combined. In addition, the self-cleaning apparatus 45 described above can be used not only for self-cleaning of the cleaning members 43 and 43′ that have cleaned the polished substrate W but also for self-cleaning when unused cleaning members 43 and 43′ are used for the first time (so-called break-in).

As described above, in the present embodiment, the cleaning member 43 is pressed against the plate 46 provided with the holes 46a to self-clean the cleaning member 43. Since the contaminated liquid discharged from the cleaning member 43 is discharged below the plate 46 via the holes 46a, the contaminated liquid can be suppressed from being reabsorbed into the cleaning member 43, and the cleaning member 43 can be efficiently self-cleaned.

Based on the above description, a person skilled in the art may be able to conceive additional effects and various modifications of the present invention, but aspects of the present invention are not limited to the individual embodiments described above. Various additions, modifications, and partial deletions can be made without departing from the conceptual idea and spirit of the present invention derived from the contents defined in the claims and equivalents thereof.

For example, what is described in the present specification as a single apparatus (alternatively, a member, the same applies hereinafter) (including what is depicted in the drawings as a single apparatus) may be implemented by a plurality of apparatuses. Conversely, what is described in the present specification as a plurality of apparatuses (including what is depicted in the drawings as a plurality of apparatuses) may be implemented by one apparatus. Alternatively, some or all of the means and functions included in a certain apparatus may be included in another apparatus.

In addition, not all the matters described in the present specification are essential requirements. In particular, matters described in the present specification and not described in the claims can be regarded as arbitrary additional matters.

It should be noted that the applicant of the present invention is merely aware of the invention disclosed in the document in the column of “prior art document” in the present specification, and the present invention is not necessarily intended to solve the problem in the invention disclosed in the document. The problem to be solved by the present invention should be recognized in consideration of the entire specification. For example, in the present specification, in a case where there is a description that a predetermined effect is exhibited by a specific configuration, it can be said that the problem of reversing the predetermined effect is solved. However, such a specific configuration is not necessarily an essential requirement.

### REFERENCE SIGN LISTS

100 substrate processing apparatus
1 housing
2 load port
3a to 3d substrate polishing apparatus
4, 4a, 4b substrate cleaning apparatus
41 substrate holding and rotating mechanism
42 cleaning liquid supply nozzle
43, 43′ cleaning member
43a rotation axis
44 swing arm
45 self-cleaning apparatus
46 plate
46a, 46b hole
461 discharger
47 casing
48 depressurizing mechanism
49 nozzle
4A heating member
4B sensor
5 substrate drying apparatus
6a to 6d substrate transport apparatus

What is claimed is:

1. A substrate cleaning apparatus comprising:
a cleaning member configured to clean a substrate;
a plate having a horizontal plane provided with a hole; and
a pressing mechanism configured to press the cleaning member vertically downward against the plate, wherein
the hole penetrates the plate, and a liquid discharged from the cleaning member is discharged below via the hole, whereby absorption of the liquid discharged from the cleaning member into the cleaning member is suppressed.

2. The substrate cleaning apparatus according to claim 1, further comprising:
a casing provided in a lower portion of the plate; and
a depressurizing mechanism configured to depressurize an inside of the casing.

3. The substrate cleaning apparatus according to claim 1, further comprising a nozzle configured to supply a cleaning liquid to the plate.

4. The substrate cleaning apparatus according to claim 1, wherein the pressing mechanism rotates the cleaning member while pressing the cleaning member against the plate.

5. The substrate cleaning apparatus according to claim 4, wherein the hole is not provided at a position where the cleaning member comes into contact in the plate.

6. The substrate cleaning apparatus according to claim 1, further comprising a heating member configured to heat the plate.

7. The substrate cleaning apparatus according to claim 1, further comprising a sensor provided at a position in contact with the cleaning member and capable of detecting a contamination state of the cleaning member.

8. The substrate cleaning apparatus according to claim 7, wherein the plate is provided with a second hole for sensor arrangement, and the sensor is provided in the second hole.

9. The substrate cleaning apparatus according to claim 8, wherein an upper surface of the sensor and an upper surface of the plate are substantially flush with each other.

10. The substrate cleaning apparatus according to claim 7, wherein the sensor is a pH measuring instrument or a conductivity meter.

11. The substrate cleaning apparatus according to claim 1, further comprising a substrate holding and rotating mechanism configured to hold and rotate a substrate in a horizontal direction, wherein
a lower surface of the cleaning member cleans an upper surface of the substrate, and
the pressing mechanism presses the lower surface of the cleaning member against the plate.

12. The substrate cleaning apparatus according to claim 11, wherein
the pressing mechanism is a swing arm,
when cleaning the substrate, the swing arm swings the cleaning member on the substrate while the swing arm presses the cleaning member vertically downward against the upper surface of the substrate, and
when cleaning the cleaning member, the swing arm presses the cleaning member vertically downward against the plate.

13. A substrate processing apparatus comprising:
a substrate polishing apparatus configured to polish a substrate using a slurry;
the substrate cleaning apparatus according to claim 1 that cleans the polished substrate; and
a substrate drying apparatus configured to dry the cleaned substrate.

14. An apparatus for cleaning a cleaning member, the apparatus comprising:
a plate having a horizontal plane provided with a hole; and
a pressing mechanism configured to press a cleaning member for cleaning a substrate vertically downward against the plate, wherein
the hole penetrates the plate, and a liquid discharged from the cleaning member is discharged below via the hole, whereby absorption of the liquid discharged from the cleaning member into the cleaning member is suppressed.

15. A method for cleaning a cleaning member, the method comprising
a process of pressing a cleaning member for cleaning a substrate vertically downward against a plate having a horizontal plane provided with a hole, wherein
the hole penetrates the plate, and a liquid discharged from the cleaning member is discharged below via the hole, whereby absorption of the liquid discharged from the cleaning member into the cleaning member is suppressed.
